(19) United States
(12) Patent Application Publication
(10) Pub. No.: US 2006/0051899 A1
(43) Pub. Date: Mar. 9, 2006

(54) Method of forming precision leads on a chip-supporting leadframe

(75) Inventor: Jeffrey Lien, Taipei City (TW)

Correspondence Address: TROXELL LAW OFFICE PLLC, SUITE 1404, 5205 LEESBURG PIKE, FALLS CHURCH, VA, 22041, US

(73) Assignee: Optimum Care International Tech. Inc.

(21) Appl. No.: 11/059,418

(22) Filed: Feb. 17, 2005

(30) Foreign Application Priority Data
Sep. 3, 2004 (TW) 093106238

(51) Int. Cl. H01L 21/50

(52) U.S. Cl. 438/123

(57) ABSTRACT

A method of forming precision leads on a chip-supporting leadframe includes the step of having each of the leads plated at a lower side with a metal substance to directly form one or more conducting sections and outer conducting planes, such that the non-plated area of the lower side of each lead defines an inner conducting plane for electrically conductively contacting with a chip supported on a top of the leadframe. The conducting sections and the outer conducting planes directly plated on the leads have precise and stable sizes and allow the leadframe to have a reduced volume. The metal substance for plating maybe gold, silver, copper, etc., depending on actual need, so as to increase the conductivity and reduce the resistance of the leads.

### FIELD OF THE INVENTION

The present invention relates to a method of forming precision leads on a chip-supporting leadframe, and more particularly to a method of forming precision leads on a chip-supporting leadframe by way of plating the leads with a metal substance.

### BACKGROUND OF THE INVENTION

FIG. 6 is a bottom view of a conventional chip-supporting leadframe 10. As shown, the leadframe 10 includes a plurality of sequentially arranged pin-shaped leads 101 formed by pressing, so that the leads 101 function like a medium to electrically connect a chip 20 supported on a top of the leadframe 10 to external elements. FIG. 7 shows the manner in which the leads 101 are associated with the chip 20. As shown, the leads 101 of the leadframe 10 are arranged at two lower lateral sides of the chip 20, and electrically connected to the chip 20 via a metal wire 30 each. Finally, the leadframe 10 and the chip 20 are packaged using a sealing material 40 to seal the chip 20 and the metal wires 30 with the pin-shaped leads 101 projected from two lateral sides of the sealing material 40 for electrically connecting to external elements.

It is known that products made by way of pressing have shape and size frequently affected by the accuracy and wearing state of molds thereof, as well as the hardness of materials being processed to form the products. Therefore, it is difficult to fully control the shape and size of the finished products, particularly when the molds have been repeatedly used to have increased errors in their dimensions and require calibration or correction again and again. Therefore, it is uneasy to control the precision and quality of the leads 101 on the leadframe 10 when they are made by pressing.

Generally, it is most preferable to use copper (Cu) as the material for forming the leads 101 because copper has a low resistance value of 1.673 IW-cm at 20° C. However, gold (Au) is the best choice for forming the leads 101 in terms of its good electric conductivity. When the leads 101 are formed by way of pressing, it is impossible to directly combine these two types of metal materials. That is, the leads 101 must be formed through pressing and then plated with gold. These procedures inevitably complicate the manufacturing process of the leads 101 and increase the manufacturing costs thereof.

Moreover, the conventional pin-shaped leads 101 have outer ends projected from two lateral sides of the sealing material 40, preventing a transistor assembled from the leadframe 10 and chip 20 from having a reduced volume and increasing the resistance value of the leads 101. Thus, the conventional leadframe 10 having projected leads 101 formed through pressing apparently fails to meet the requirements of current electronic industrial field for compact products that provide high transmission rate.

### SUMMARY OF THE INVENTION

A primary object of the present invention is to provide a method of forming precision leads on a chip-supporting leadframe, in which each of the leads is plated with a metal substance to form at least one conducting section at a selected position on a lower side of the lead; a bottom side of each plated conducting section defines an outer conducting plane for each lead; and the rest area of the lower side of each lead adjacent to the conducting section functions like an inner conducting plane for electrically conductively contact a chip supported on a top of the leadframe, so that the leadframe may be formed in a simplified manner and have reduced volume as well as accurate size and quality.

Another object of the present invention is to provide a method of forming precision leads on a chip-supporting leadframe by way of plating the leads with a metal substance, so that at least one conducting section is formed at a lower side of each lead. The metal substance may be plated on the leads to form the conducting sections using anyone of currently available plating techniques, including electroplating, electroless plating, hot dip plating, spray plating, immersion plating, diffusion plating, vacuum plating, selective plating, electroforming, etc.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a bottom view schematically shows a leadframe having leads formed at four sides thereof using the method of the present invention;

FIG. 2 is bottom view schematically shows a leadframe having leads formed at two opposite sides thereof using the method of the present invention;

FIG. 3 is a fragmentary side view schematically showing that each lead formed on the leadframe using the method of the present invention includes a plated conducting section near a lower middle portion of the lead to define an outer conducting plane;

FIG. 4 is a fragmentary side view schematically showing that each lead formed on the leadframe using the method of the present invention includes a plated conducting section located at a lower outer end of the lead to define an outer conducting plane;

FIG. 5 is a fragmentary side view schematically showing that each lead formed on the leadframe using the method of the present invention includes a plurality of plated conducting sections at a lower side of the lead to define an outer conducting plane each;

FIG. 6 is a bottom view schematically showing the structure of a conventional leadframe; and

FIG. 7 is a sectional view schematically showing the packaging structure of a conventional transistor.

### DETAILED DESCRIPTION OF THE PREFERRED EMBODIMENTS

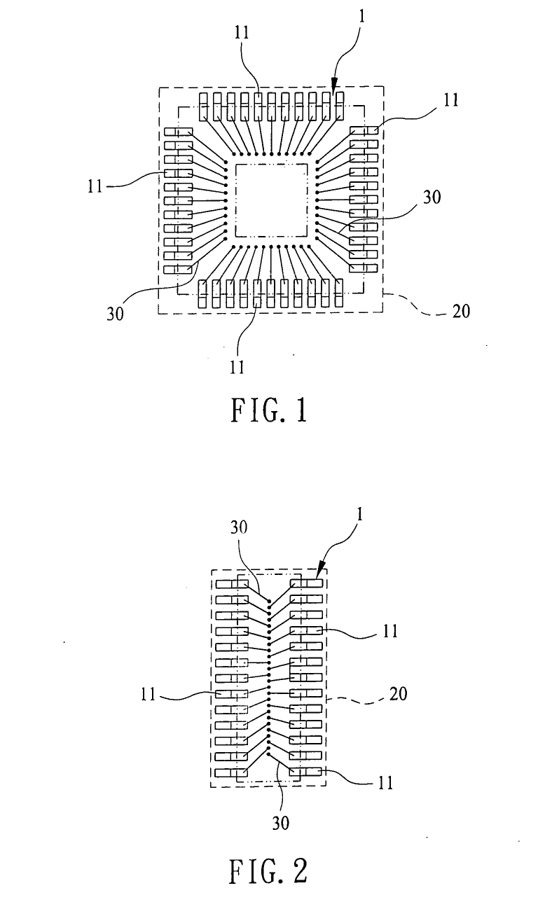

Please refer to FIGS. 1 and 2 that illustrate two examples of leadframe 1 having precision leads 11 formed thereon using the method of the present invention. In the example shown in FIG. 1, four rows of metallic leads 11 are separately formed at four sides of the leadframe 1. And, in the example shown in FIG. 2, only two rows of metallic leads 11 are formed at two opposite sides of the leadframe 1. A chip 20 is laid on a top of the leadframe 1. In either of the two examples, the leadframe 1 has the advantage of being manufactured with a simplified process to achieve reduced overall volume and precise dimensions.

It is noted the number and the placement of rows of the leads 11 on the leadframe 1 are not necessarily limited to four or two as illustrated in the two examples in FIGS. 1 and 2, respectively, but may be determined depending on actual need in manufacturing the leadframe 1.

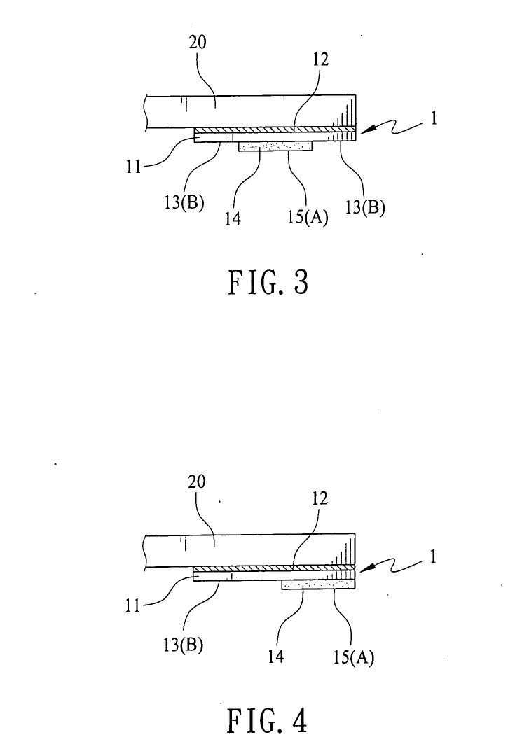

As can be seen from FIGS. 3, 4, and 5, each of the leads 11 formed on the leadframe 1 using the method of the present invention includes at least one upper supporting plane 12 defined at an upper side of the lead 11 for supporting or contacting the chip 20, and at least one conducting section 14 directly formed at a selected position on a lower side 13 of the lead 11 by way of plating the lead 11 with a specific type of metal substance, so that a bottom side 15 of the conducting section 14 defines an outer conducting plane A on the lead 11 while the lower side 13 of the lead 11 adjacent to the conducting section 14 defines an inner conducting plane B that electrically conductively contacts with the chip 20 supported on the top of the leadframe 1. That is, each of the leads 11 formed on the chip-supporting leadframe 1 using the method of the present invention includes at least one upper supporting plane 12, at least one conducting section 14 and accordingly at least one outer conducting plane A, and at least one inner conducting plane B. At least one chip 20 is supported on the leads 11 of the leadframe 1. The inner conducting plane B is electrically connected to the chip 20 via at least one metal wire 30 (see FIGS. 1 and 2), and the outer conducting plane A at the bottom side 15 of the conducting section 14 may be electrically connected to a circuit board and the like, enabling the leads 11 to function like a medium to electrically connect the chip 20 to external elements.

FIG. 3 shows a first embodiment of the method of the present invention for forming precision leads 11 on the chip-holding leadframe 1 by way of directly plating the leads 11 with a metal substance. In the embodiment shown in FIG. 3, each lead 11 is plated at the lower side 13 near a lower middle portion thereof with the metal substance to produce one plated conducting section 14 and accordingly one outer conducting plane A. Meanwhile, the rest area on the lower side 13 of the lead 11 adjacent to the plated conducting section 14 provides the inner conducting plane B.

FIG. 4 shows a second embodiment of the method of the present invention for forming precision leads 11 on the chip-holding leadframe 1 by way of directly plating the leads 11 with a metal substance. In the embodiment shown in FIG. 4, each lead 11 is plated at the lower side 13 at an outer end thereof with the metal substance to produce one plated conducting section 14 and accordingly one outer conducting plane A. Meanwhile, the rest area on the lower side 13 of the lead 11 adjacent to the plated conducting section 14 provides the inner conducting plane B.

Therefore, it is understood there is no limit to the placement of the conducting section 14 and the outer conducting plane A, and accordingly, the inner conducting plane B directly formed on each lead 11 by way of plating the lead with the metal substance at a selected position as suggested by the method of the present invention. Furthermore, it is possible to align or to stagger the conducting sections 14 on any two adjacent ones of the leads 11 sequentially arranged at two or more sides of the leadframe 1, so long as the adjacent leads 11 do not contact with each other at any soldered position reason and also avoid to have any electromagnetic interference (EMI).

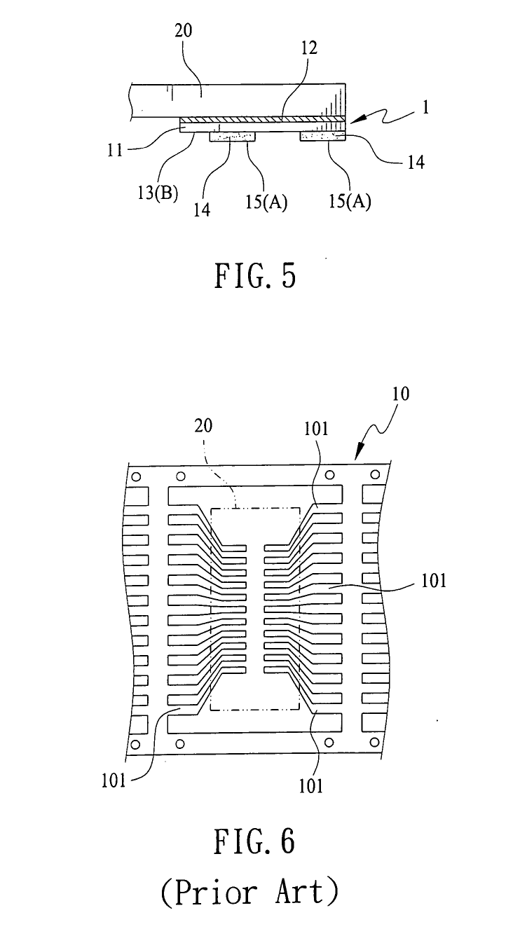

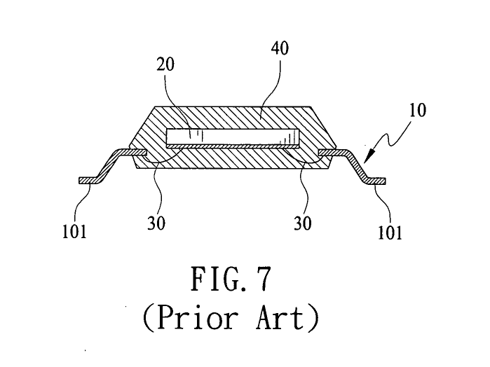

Similarly, there is no limit to the number of the plated conducting sections 14 and the outer conducting planes A on each lead 11. FIG. 5 shows a third embodiment of the method of the present invention for forming precision leads 11 on the chip-holding leadframe 1 by way of directly plating the leads 11 with a metal substance. In the embodiment shown in FIG. 5, a plurality of plated conducting sections 14 and outer conducting planes A are produced on the lower side 13 of each lead 11 as necessary for electrically connecting to external elements.

Moreover, all the currently available plating techniques for coating a surface with a metal substance may be adopted in the method of the present invention to form the precision leads 11. These existing plating techniques include, for example, electroplating, electroless plating, hot dip plating, spray plating, immersion plating, diffusion plating, vacuum plating, selective plating, electroforming, etc. And, the metal substance to be coated on the lead 11 to form the conducting section 14 may be determined depending on actual requirements in manufacturing the leadframe 1, and may therefore be gold (Au) or silver (Ag) that has a high conductivity, or copper (Cu) and any copper alloy that has a low resistance. Briefly, the lead 11 may be plated with a metal substance that is not limited to any specific type and can be easily changed depending on actual need.

The following are some advantages of the method of the present invention:

1. The plated conducting sections 14 and the outer conducting planes A, as well as the inner conducting planes B directly formed on the leads 11 have shapes and sizes that are more accurate and stable than that formed through conventional pressing, and may still be precisely modified after being formed.

2. The conducting sections 14 and the outer conducting planes A are directly formed on the lower side of the leads 11 by way of plating, which is much simpler as compared with the conventional way of forming the outer conducting ends of the leads through pressing and electroplating. The leadframe 1 can therefore be manufactured at a simplified manner and accordingly reduced costs.

3. Unlike the conventional leads 101 that are projected from the sealing material 40 to increase the volume of the leadframe 10, the outer conducting planes A directly formed at the lower side 13 of the leads 11 by way of plating as suggested by the present invention serve to electrically connect the chip 20 to external elements, and therefore allow the leadframe 1 and accordingly, the chip package assembled therefrom to have further reduced volume.

4. A transmission distance between the upper supporting plane 12 and the outer conducting plane A is shortened to enable reduced resistance value and increased transmission rate of the leads 11.

What is claimed is:

1. A method of forming precision leads on a chip-supporting leadframe, said leads being made of a metal material and sequentially arranged at two or more sides of said leadframe depending on actual need, said method comprising the step of having each of said leads plated at a lower side at a selected position with a metal substance to form at least one conducting section, each said conducting section having a bottom side defining an outer conducting plane while the rest area of the lower side of each said lead other than said at least one conducting section defining an inner conducting plane for electrically conductively contacting with a chip supported on a top of said leadframe.

2. The method of forming precision leads on a chip-supporting leadframe as claimed in claim 1, wherein said at least one conducting section and said outer conducting plane defined at the bottom side of each said conducting section are formed near a middle portion of the lower side of each said lead through plating.

3. The method of forming precision leads on a chip-supporting leadframe as claimed in claim 1, wherein said at least one conducting section and said outer conducting plane defined at the bottom side of each said conducting section are formed at an outer end of the lower side of each said lead through plating.

4. The method of forming precision leads on a chip-supporting leadframe as claimed in claim 1, wherein each of said leads is formed at the lower side with a plurality of said conducting sections, each of which defining at the bottom side thereof one said outer conducting plane.
